(19) United States
(12) Patent Application Publication
(10) Pub. No.: US 2007/0291529 A1
(43) Pub. Date: Dec. 20, 2007

(54) SEMICONDUCTOR MEMORY DEVICE

(75) Inventor: Kazuyuki MITSUYA, Ora-gun (JP)

Correspondence Address: WATCHSTONE P+D, PLC, 1250 CONNECTICUT AVENUE, N.W., SUITE 700, WASHINGTON, DC, 20036-2657, US

(73) Assignee: SANYO ELECTRIC CO., LTD., Osaka (JP)

(21) Appl. No.: 11/761,810

(22) Filed: Jun. 12, 2007

(30) Foreign Application Priority Data
Jun. 12, 2006 (JP) 2006-162703

(51) Int. Cl. G11C 7/00; G11C 11/00; G11C 7/02

(52) U.S. Cl. 365/154; 365/202; 365/206; 365/203

(57) ABSTRACT

According to some preferred embodiments of the present invention, a semiconductor memory device includes an array of memory cells and plural pairs of complementary bit lines, each pair of the complementary bit lines being connected to the memory cells arranged in the same column. The array is divided into plural memory blocks each including plural memory cells arranged in the same column. The corresponding complementary bit lines of the plural memory blocks are connected to corresponding common complementary data lines, respectively. Some pairs of the complementary data lines are crossed at least one time so that the complementary data lines of each pair of the some pairs of the complementary data lines are reversed in position and that the crossed data line and a non-cross data line are arranged alternately whereby crosstalk to be generated between adjacent data lines are reduced.

This application claims priority under 35 U.S.C. §119 to Japanese Patent Application No. 2006-162703 filed on Jun. 12, 2006, the entire disclosure of which is incorporated herein by reference in its entirety.

### BACKGROUND OF THE INVENTION

1. Field of the Invention

The present invention relates to a semiconductor memory device. More specifically, some preferred embodiments of the present invention relate to a semiconductor memory device having SRAMs (Static Random Access Memories).

2. Description of the Related Art

The following description sets forth the inventor's knowledge of related art and problems therein and should not be construed as an admission of knowledge in the prior art.

As one of semiconductor memory devices, a semiconductor memory device having SRAMs is known. An SRAM is one of random access memories (RAM) capable of performing writing and reading operations without requiring refresh operations so long as a power supply voltage is being applied.

FIG. 1 shows an example of an SRAM used as a memory cell. In this case, the first inverter 1 and the second inverter 2 constitute a latch circuit in which the input and the output are cross-linked. The gate of the first access transistor 3 and that of the second access transistor 4 are connected to a common word line WL. The first access transistor 3 connects the first memory node 5 and the bit line BL, and the second access transistor 4 connects the second memory node 6 and the complementary bit line BLB.

Such a SRAM has been widely used, for example, as a memory for use in a microcomputer. In a microcomputer for an LCD driver for driving an LCD panel, it is required to have a large memory capacity. In this case, if all of the memory cells are to be precharged, the operating speed deteriorates. To solve this problem, a divided precharge type semiconductor memory device is proposed. This device is configured such that an array of memory cells is divided into plural blocks and precharged every block unit.

FIG. 5 shows a block diagram of an example of a precharge type semiconductor memory device according to a related art. In this semiconductor memory device, the array of memory cells includes a first memory block 7, a second memory block 8, a third memory block 9, and a fourth memory block 10. Although not illustrated here, each memory block has plural word lines WL and plural pairs of complementary bit lines BL and BLB. At each intersection of the world lines WL and the complementary bit lines BL and BLB, a memory cell is arranged. The first memory block 7, the second memory block 8, the third memory block 9, and the fourth memory block 10 have a first precharge circuit 7P, a second precharge circuit 8P, a third precharge circuit 9P, and a fourth precharge circuit 10P, respectively. Furthermore, the first memory block 7, the second memory block 8, the third memory block 9, and the fourth memory block 10 have a first sense amplifier 11, a second sense amplifier 12, a third sense amplifier 13 and a fourth sense amplifier 14, respectively.

At the time of performing a reading operation, each precharge circuit precharges all of the bit lines BL and the complementary bit lines BLB in each memory block. In this precharged state, an H-potential is applied to a line-specified work line WL. As a result, depending on the data of the complementary first and second memory nodes 5 and 6, the precharged state of one of the bit lines BL and BLB will be released, and the precharged state of the other bit line will be maintained. Next, only the data of the column-specified complementary bit lines DL and DLB will be outputted to each of the complementary data lines DL and DLB via each sense amplifier 11, 12, 13 and 14.

In the aforementioned semiconductor memory device, since the array of memory cells is divided into a predetermined number of memory blocks and that memory cells to be precharged at the time of performing a single access are limited to the memory cells in the selected memory block, the power consumption can be reduced.

In this case, however, it was required that the data lines DL and the complementary data lines DLB connect the corresponding bit lines BL of the memory blocks 7, 8, 9 and 10 and the corresponding complementary bit lines BLB of the memory blocks 7, 8, 9 ad 10, respectively. Accordingly, the data line DL and the complementary data line DLB increase in length in accordance with the number of bits. As a result, in the semiconductor memory device, at the time of performing a reading operation, when the potential of adjacent both data lines changes into an L-potential, the effects of crosstalk to be generated to the data line DL or the complementary data line DLB surrounded by them increase. Conventionally, the effects of crosstalk were prevented by increasing the distance between the adjacent data lines DL and that between the adjacent complementary data lines DLB. This causes the entire size of the memory device.

The description herein of advantages and disadvantages of various features, embodiments, methods, and apparatus disclosed in other publications is in no way intended to limit the present invention. For example, certain features of the preferred embodiments of the invention may be capable of overcoming certain disadvantages and/or providing certain advantages, such as, e.g. disadvantages and/or advantages discussed herein, while retaining some or all of the features, embodiments, methods, and apparatus disclosed therein.

### SUMMARY OF THE INVENTION

The preferred embodiments of the present invention have been developed in view of the above-mentioned and/or other problems in the related art. The preferred embodiments of the present invention can significantly improve upon existing methods and/or apparatuses.

Among other potential advantages, some embodiments can provide a semiconductor memory device with less crosstalk.

Among other potential advantages, some embodiments can provide a divided precharge type semiconductor memory device capable of decreasing crosstalk without increasing the size of the device even if data lines are long.

According to one aspect of the present invention, a semiconductor memory device, comprising:

an array of memory cells; and

plural pairs of complementary bit lines, each pair of the complementary bit lines being connected to the memory cells arranged in the same column,

wherein the array is divided into plural memory blocks each including plural memory cells arranged in the same column,

wherein corresponding complementary bit lines of the plural memory blocks are connected to corresponding common complementary data lines, respectively, and

wherein some pairs of the complementary data lines are crossed at least one time so that the complementary data lines constituting each pair of the some pairs of the complementary data lines are reversed in position and that the crossed data line and a non-crossed data line are arranged alternately.

With this structure, it becomes possible to prevent the electrical potentials of the data lines or complementary data lines arranged at both sides of the data line or the complementary data line from becoming L-potentials. As a result, the capacity between the data lines decreases, which in turn can suppress the effects of crosstalk without increasing the distance between the data lines.

In the aforementioned semiconductor memory device, it should be understood that the number of crossing the data lines and the position of crossing the data lines are not specifically limited. For example it can be configured that some of plural pairs of the complementary data lines are crossed several times and the other pairs of the complementary data lines remain non-crossed. In this case, a reversed portion of one of the complementary data lines and a non-reversed portion of the other of the complementary data lines are preferably the same in length.

Furthermore, it is preferable that half of the plural pairs of the complementary data lines are crossed one time at a longitudinal intermediate position of the data line and the other half thereof remains non-crossed. With this structure, the effects of crosstalk can be effectively suppressed.

The present invention can be preferably applied to a semiconductor memory device having an array of memory cells grouped into plural memory blocks each comprising static random access memories (SRAMs) in which precharge is performed every memory block. However, the present invention is not limited to the above, and can also be applied to a semiconductor memory device having an array of memory cells grouped into plural blocks each having random access memories, such as, e.g., a DRAM.

The above and/or other aspects, features and/or advantages of various embodiments will be further appreciated in view of the following description in conjunction with the accompanying figures various embodiments can include and/or exclude different aspects, features and/or advantages where applicable. In addition, various embodiments can combine one or more aspect or feature of other embodiments where applicable. The descriptions of aspects, features and/or advantages of particular embodiments should not be construed as limiting other embodiments or the claims.

### BRIEF DESCRIPTION OF THE DRAWINGS

The preferred embodiments of the present invention are shown by way of example, and not limitation, in the accompanying figures, in which:

FIG. 1 is an example of a memory cell constituting a semiconductor memory device;

FIG. 2 is an explanatory view showing memory blocks and wiring of data lines of a semiconductor memory device according to an embodiment of the present invention;

FIG. 3 is an explanatory view showing one of memory blocks of the semiconductor memory device according to the embodiment of the present invention;

FIG. 4 is an enlarged view showing a crossing area of data lines of the semiconductor memory device according to the embodiment of the present invention; and

FIG. 5 is an explanatory view showing memory blocks and wiring of data lines of a semiconductor memory device according to a related art.

### DETAILED DESCRIPTION OF THE PREFERRED EMBODIMENTS

In the following paragraphs, some preferred embodiments of the present invention will be described by way of example and not limitation. It should be understood based on this disclosure that various other modifications can be made by those in the art based on these illustrated embodiments.

A semiconductor memory device according to an embodiment of the present invention will be explained with reference to the attached drawings.

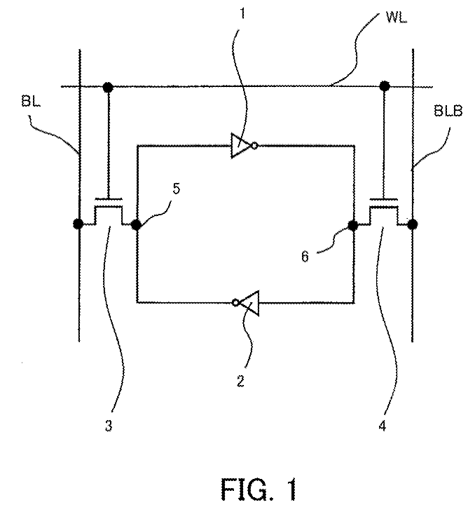

Initially, a memory cell constituting a semiconductor memory device according to an embodiment of the present invention will be explained FIG. 1 shows an example of an SRAM used as a memory cell.

This memo cell includes a first inverter 1, a second inverter 2, a first access transistor 3 and a second access transistor 4. The first inverter 1 and the second inverter 2 constitute a latch circuit in which the input and the output are cross-linked. The gate of the first access transistor 3 and that of the second access transistor 4 are connected to a common word line WL. The first access transistor 3 connects the first memory node 5 and the bit line BL, and the second access transistor 4 connects the second memory node 6 and the complementary bit line BLB.

The operation of the aforementioned SRAM will be explained. Initially both the bit line BL and the complementary bit line BLB are precharged by being applied by an H-potential. In this precharged state, when an H-potential is applied to the word line WL, the first access transistor 3 and the second access transistor 4 will be turned on, so that the first memory node 5 will be connected to the bit line BL, and the second memory node 6 will be connected to the complementary bit line BLB. As a result, according to the complementary data of the first memory node 5 and the second memory node 6, one of the precharged state of the bit lines BL and BLB will be released, and the other will be maintained. Then, the potential difference between the complementary bit lines BL and BLB will be read out as the information of the memory cell.

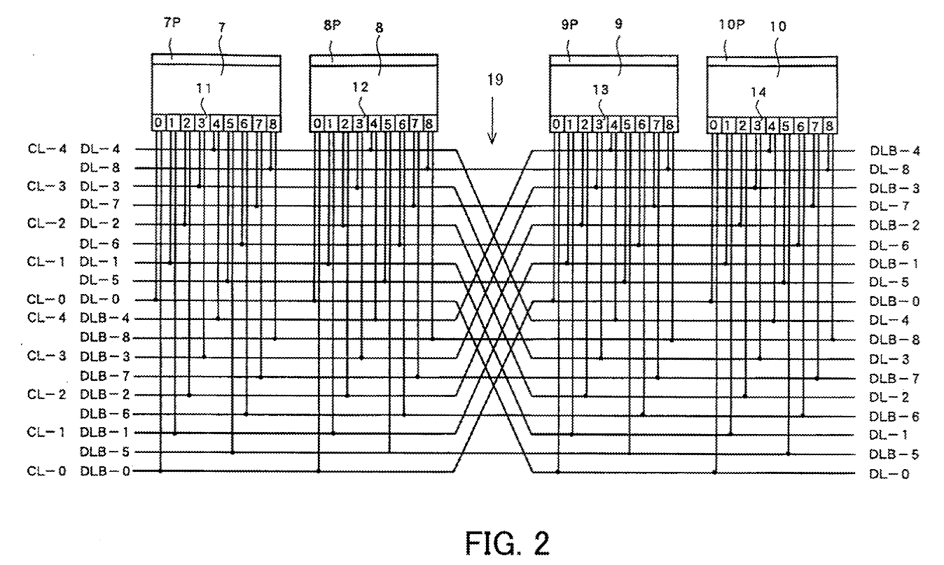

Now, a semiconductor memory device according to an embodiment of the present invention in which the aforementioned SRAM is used as a memory cell will be explained. FIG. 2 is an explanatory view showing memory blocks and wiring of data lines of the semiconductor memory device according to the embodiment of the present invention. In this semiconductor memory device, the array of memory cells is divided into a plurality of memory blocks (i.e., four memory blocks 7, 8, 9 and 10), so that the memory cells can be precharged each memory block unit 7, 8, 9 or 10. This divided precharge type memory device is preferably used in, e.g., a microcomputer requiring a large memory capacity or an LCD driver for driving a liquid crystal display panel.

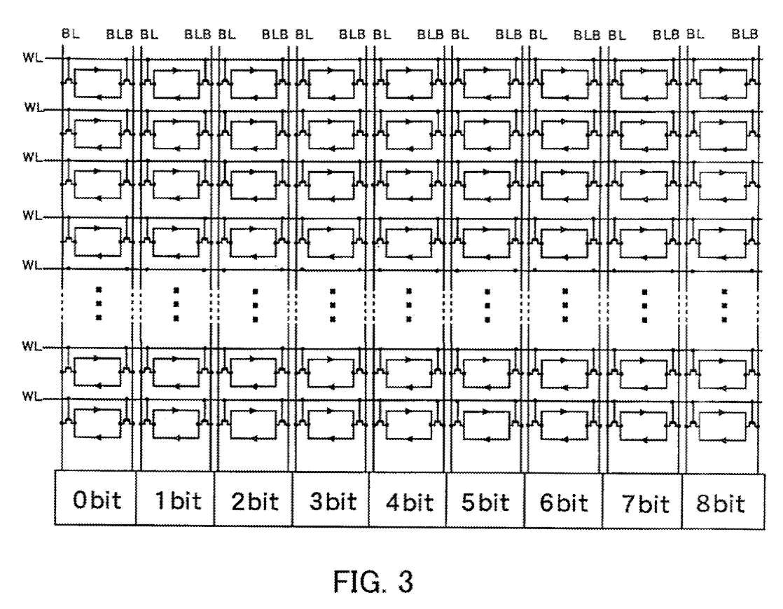

This memory cell array is constituted by the first memory block 7, the second memory block 8, the third memory block 9, and the fourth memory block 9. As shown in FIG. 3, each memory block has a plurality of word lines WL, plural pairs of bit lines BL and complementary bit lines BLB intersecting with the word lines WL. Each memory cell is located at the portion corresponding to the intersections of the word lines WL, the bit line BL and the complementary bit line BLB. For example, in a 36-bit semiconductor memory device, each memory block has 9 (nine) columns of memory cells, and 4 (four) memory blocks are formed.

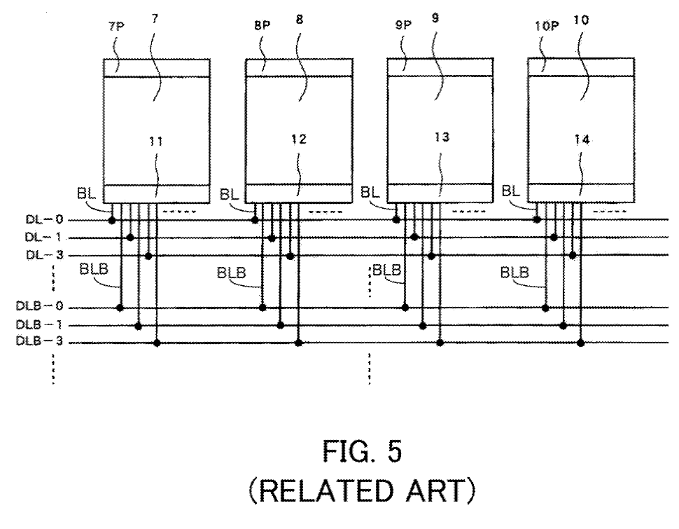

Conventionally, as shown in FIG. 5, the bit lines BL and the complementary bit lines BLB of each memory block are connected to the corresponding data lines DL and complementary data lines DLB. More specifically, as to the first memory block 7, the bit line BL and the complementary bit line BLB connected to the 0-bit column memory cells are connected to the data line DL-0 and the complementary data line DLB-0, restively. The bit line BL and the complementary bit line BLB connected to the 1-bit column memory cells are connected to the data line DL-1 and the complementary data line DLB-1, respectively. The bit line BL and the complementary bit line BLB connected to the 2-bit column memory cells are connected to the data line DL-3 and the complementary data line DLB-3, respectively. In this manner, the bit lines BL and the complementary bit lines BLB of each memory block are connected to the corresponding data lines DL-0, DL-1, DL-3 . . . and complementary data lines DLB-0, DLB-1, DLB-3 . . . , respectively.

As to the second memory block 8, the third memory block 9 and the fourth memory block 10, in the same manner as in the first memory block 7, the bit lines BL and the complementary bit lines BLB of each memory block 8, 9 and 10 are connected to the corresponding common data lines DL-0, DL-1, DL-3 . . . , and complementary data lines DLB-0, DLB-1, DLB-3 . . . , respectively.

Thus, the data outputted from the bit lines BL and the complementary bit lines BLB connected to each memory block 7, 8, 9, and 10 will be outputted to the corresponding data lines DL and complementary data lines DLB via each sense amplifier 11, 12, 13, and 14. As will be apparent from FIG. 5, the data outputted from the corresponding bit-column of each memory block 7, 8, 9, 10 will be outputted to the same data line DL or the same complementary data line DLB. For example, in each memory block, the data from the first column memory cells of the memory block will be outputted to the data line DL-0 and the complementary data line DLB-0. The data line DL-0 and the complementary data line DLB-0 are in a complementary relation.

The operation of the aforementioned semiconductor memory device will be explained. Initially, the bit lines BL and the complementary bit lines BLB of a selected memory block 7, 8, 9, or 10 will be precharged with the corresponding one of the first precharge circuit 7P, the second precharge circuit 8P, the third precharge circuit 9P and the fourth precharge circuit 10P. With this precharged state, an H-potential is applied to a line-specified word line WL. As a result, depending on the data of the first memory node 5 and the second memory node 6 having complementary levels, the precharge state of one of the bit line BL and the complementary bit line BLB will be released, and the precharge state of the other will be maintained. Then, only the data of the column-specified bit line BL or the complementary bit line BLB will be outputted to the data line DL or the complementary data line DLB.

In this structure, as previously explained, in proportion to the length of the data line DL and that of the complementary data line DLB, the effects of the crosstalk to be generated on the data line DL and the complementary data line DLB increase. For example, when the electrical potential of the data line DL or the complementary data line DLB changes, the electrical potential of another data line DL or complementary data line DLB located adjacent to the data line DL or the complementary data line DLB may also change, which in turn may sometime cause information rewriting.

In order to solve the aforementioned problem, the embodiment of the present invention utilizes that the data line DL and the complementary data line DLB connected to the memory cells arranged in the same column in a memory block or corresponding another memory block are in a complementary state.

In this embodiment, as shown in FIG. 2, 5 (five) pairs of the complementary data lines DL-O and DLB-0, DL-1 and DLB-1, DL-2 and DLB-2, DL-3 and DLB-3, DL-4 and DLB-4 are crossed at a longitudinal intermediate area 19 located between the second memory block 8 and the third memory block 9 so that data line positions of each pair of the complementary data lines DL-0 and DLB-0, DL-1 and DLB-1, DL-2 and DLB-2, DL-3 and DLB-3, DL-4 and DLB-4 are reversed and that the crossed data line DL-4, DL-3, DL-2, DL-1 DL-0, DLB-4, DLB-3, DLB-2, DLB-1 and DLB-0 and a non-crossed data line D-8, DL-7, DL-6, DL-5, DLB-8, DLB-7, DLB-6, DLB-5 are arranged alternately.

In detail, as shown in FIG. 2, the uppermost data line forms a complex line CL-4 constituted by a half of the data line DL-4 and a half of the complementary data line DLB-4. The third data line from the uppermost data line DL-4 forms a complex data line CL-3 constituted by a half of the data line DL-3 and a half of the complementary data line DL-3. The fifth data line from the uppermost data line DL-4 forms a complex data line CL-2 constituted by a half of the data line DL-2 and a half of the complementary data line DLB-2. The seventh data line from the uppermost data line DL-4 forms a complex data line CL-1 constituted by a half of the data line DL-1 and a half of the complementary data line DLB-1. The ninth data line from the uppermost data line DL-4 forms a complex data line CL-0 constituted by a half of the data line DL-0 and a half of the complementary data line DLB-0. The tenth data line from the uppermost data line DL-4 forms a complex data line CL-4 constituted by a half of the data line D-4 and a half of the complementary data line DL-4. The twelfth data line from the uppermost data line DL-4 forms a complex data line CL-3 constituted by a half of the data line DLB-3 and a half of the complementary data line DL-3. The fourteenth data line from the uppermost data line DL-4 forms a complex data line CL-2 constituted by a half of the data line DLB-2 and a half of the complementary data line DL-2. The sixteenth data line from the uppermost data line DL-4 forms a complex data line CL-1 constituted by a half of the data line DLB-1 and a half of the complementary data line D-1. The eighteenth data line from the uppermost data line DL-4 forms a complex data line CL-0 constituted by a half of the data line DLB-0 and a half of the complementary data line DL-0.

Thus, in the embodiment shown in FIG. 2, the complex data lines CL-4, CL-3, CL-2, CL-1, and CL-0 and the non-complex data lines DL-8, DL-7, DL-6, DL-5 are arranged alternately. In the same manner, the complex data line CL-4, CL-3, CL-2, CL-1, and CL-0 and the non-complex data lines DLB-8, DLB-7, DLB-6 ad DLB-5 are arranged alternately.

With this structure, the potential of each complex data line CL will always be a combination of an H-potential and an L-potential. Therefore, each non-complex data line DL-8, DL-7, DL-6, DL-5 will not be surrounded by L-potentials along the entire length. Furthermore, each complex data line CL-4, CL-3, CL-2, CL-1, CL-0 itself is also divided into an H-potential and an L-potential. Thus, the length surrounded by L-potentials is also divided. In other words, according to the semiconductor memory device of the aforementioned embodiment, regardless of the data storing state, crosstalk will be assuredly decreased as compared with a conventional semiconductor memory device.

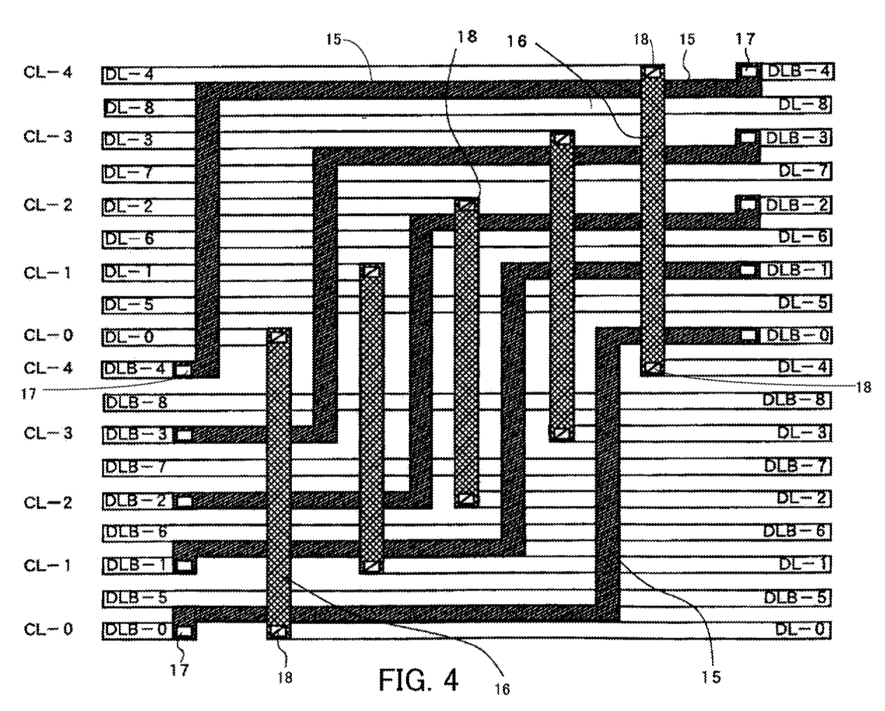

The aforementioned crossing of the data lines can be performed as shown by, e.g., FIG. 4. FIG. 4 shows a vicinity of the crossing area 19 where the data lines are crossed. In this embodiment, the semiconductor memory device has a three-layer structure. The aforementioned complex data line CL is formed by utilizing a second layer's contact holes 17 and the second layer's crossing line 15 or a third layer's contact holes 18 and the third layer's crossing line 16. In detail, the uppermost left side data line DL-4 is connected to the tenth right side data line DL-4 from the uppermost lift side data line DL-4 via the third layer's contact holes 18 and the third layer's crossing line 16. The tenth left side complementary data line DLB-4 from the uppermost data line DL-4 is connected to the uppermost right side complementary data line DLB-4 via the second layer's contact holes 17 and the second layer's crossing line 15. In the same manner, the rest of the data lines are crossed in this crossing area 19.

As will be understood from the above, in the aforementioned divided precharge type semiconductor memory device, even if the length of the data line DL and that of the complementary data line DLB become long, effects of crosstalk can be suppressed without increasing the entire area (size) of the memory device.

In the aforementioned embodiment, although each of the data lines DL-4, DL-3, DL-2, DL-1, DL-0, DLB-4, DLB-3, DLB-4, DLB-1, DLB-O is crossed one time at the longitudinal intermediate portion, the number and position of crossing the data lines are not specifically limited. For example, it can be configured that some of the plural pairs of the complementary data lines are crossed several times at several positions and the remaining pairs of the complementary data lines remain non-crossed. In this case, the reversed portion of the crossed data line and the non-reversed portion of the crossed data line are preferably set to the same in length to attain the effects mentioned above. Furthermore, it is preferable that half of the plural pairs of the complementary data lines are crossed one time at a longitudinal intermediate position of the data line and the other half thereof remains non-crossed. With this structure, the effects of crosstalk can be effectively suppressed.

The aforementioned explanation was directed to a divided precharge type semiconductor memory device having static random access memories (SRAMs) in which precharge is performed every memory block. However, it should be understood that the present invention is not limited to be above, and can also be applied to a semiconductor memory device having an array of memory cells grouped into plural blocks each having random access memories, such as, e.g., a DRAM.

While the present invention may be embodied in many different forms, a number of illustrative embodiments are described herein with the understanding that the present disclosure is to be considered as providing examples of the principles of the invention and such examples are not intended to limit the invention to preferred embodiments described herein and/or illustrated herein.

While illustrative embodiments of the invention have been described herein, the present invention is not limited to the various preferred embodiments described herein, but includes any and all embodiments having equivalent elements, modifications, omissions, combinations (e.g., of aspects across various embodiments), adaptations and/or alterations as would be appreciated by those in the art based on the present disclosure. The limitations in the claims are to be interpreted broadly based on the language employed in the claims and not limited to examples described in the present specification or during the prosecution of the application, which examples are to be construed as non-exclusive. For example, in the present disclosure, the term “preferably” is non-exclusive and means “preferably, but not limited to.” In this disclosure and during the prosecution of this application, means-plus-function or step-plus-function limitations will only be employed where for a specific claim limitation all of the following conditions are present in that limitation: a) “means for” or “step for” is expressly recited; b) a corresponding function is expressly recited; and c) structure, material or acts that support that structure are not recited. In this disclosure and during the prosecution of this application, the terminology “present invention” or “invention” is meant as an non-specific, general reference and may be used as a reference to one or more aspect within the present disclosure. The language present invention or invention should not be improperly interpreted as an identification of criticality, should not be improperly interpreted as applying across all aspects or embodiments (i.e., it should be understood that the present invention has a number of aspects and embodiments), and should not be improperly interpreted as limiting the scope of the application or claims. In this disclosure and during the prosecution of this application, the terminology “embodiment” can be used to describe any aspect, feature, process or step, any combination thereof, and/or any portion thereof, etc. In some examples, various embodiments may include overlapping features. In this disclosure and during the prosecution of this case, the following abbreviated terminology may be employed: “e.g.” which means “for example;” and “NB” which means “note well.”

What is claimed is:

1. A semiconductor memory device, comprising:
an array of memory cells; and
plural pairs of complementary bit lines, each pair of the complementary bit lines being connected to the memory cells arranged in the same column,
wherein the array is divided into plural memory blocks each including plural memory cells arranged in the same column,
wherein corresponding complementary bit lines of the plural memory blocks are connected to corresponding common complementary data lines, respectively, and
wherein some pairs of the complementary data lines are crossed at least one time so that the complementary data lines constituting each pair of the some pairs of the complementary data lines are reversed in position and that the crossed data line and a non-crossed data line are arranged alternately.

2. The semiconductor memory device as recited in claim 1, wherein half of the plural pairs of the complementary data lines are crossed one time and the other half thereof remains non-crossed.

3. The semiconductor memory device as recited in claim 2, wherein the complementary data lines are crossed at a longitudinal intermediate position thereof.

4. The semiconductor memory device as recited in claim 1, wherein a reversed portion of one of the complementary data lines and a non-reversed portion of the other of the complementary data lines are the same in length.

5. The semiconductor memory device as recited in claim 1, wherein the memory cell is constituted by a static random access memory (SRAM).

6. The semiconductor memory device as recited in claim 1, wherein the memory cells are configured to be precharged every memory block.

7. The semiconductor memory device as recited in claim 1, wherein the memory cells are memories for use in a liquid crystal display (LCD) driver.

8. A semiconductor memory device, comprising:
an array of memory cells divided into plural memory blocks each including plural memory cells arranged in the same column;
plural word lines connected to the memory cells;
plural pairs of complementary bit lines, each pair of the complementary bit lines being connected to the memory cells arranged in the same column;
plural pairs of complementary data lines to which corresponding complementary bit lines of the plural memory blocks are connected; and
plural precharge circuits each for precharging a corresponding memory block,
wherein half pairs of the complementary data lines are crossed one time at a longitudinal intermediate portion thereof so that the complementary data lines constituting each pair of the complementary data lines are reversed in position and remaining pairs of the complementary data lines remain non-crossed, and
wherein a complex data line constituted by a reversed portion of one of the complementary data lines and a non-reversed portion of the other of the complementary data lines and a non-complex data line constituted by a non-crossed data line or a non-crossed complementary data line are arranged alternately.

9. The semiconductor memory device as recited in claim 8, wherein the memory cell is constituted by a static random access memory (SRAM).

10. The semiconductor memory device as recited in claim 8, wherein the memory cells are memories for use in a liquid crystal display (LCD) driver.
